(19) United States
(12) Patent Application Publication
(10) Pub. No.: US 2021/0195738 A1
(43) Pub. Date: Jun. 24, 2021

(54) ELECTRONIC APPARATUS, CIRCUIT BOARD AND METHOD OF MANUFACTURING THE SAME

(71) Applicants: Beijing BOE Sensor Technology Co., Ltd., Beijing (CN); BOE TECHNOLOGY GROUP CO., LTD., Beijing (CN)

(72) Inventors: Fengchun PANG, Beijing (CN); Yue LI, Beijing (CN); Xue CAO, Beijing (CN)

(21) Appl. No.: 16/908,790

(22) Filed: Jun. 23, 2020

(30) Foreign Application Priority Data
Dec. 20, 2019 (CN) 201911330953.3

(51) Int. Cl. H05K 1/11; H05K 1/05; H05K 3/40; H05K 3/46

(52) U.S. Cl. CPC H05K 1/115; H05K 3/4644; H05K 3/4038; H05K 1/056

(57) ABSTRACT

The present disclosure provides an electronic apparatus, a circuit board, and a method of manufacturing the same, which belongs to the field of circuit board technology. The method of manufacturing the circuit board includes: providing a base substrate, forming a first circuit layer on a side of the base substrate, and performing first to N-th circuit stacking operations in sequence, where an n-th circuit stacking operation comprises forming an n-th dielectric layer on a side of an n-th circuit layer away from the base substrate, the n-th dielectric layer having at least one n-th via exposing the n-th circuit layer provided therein, and forming an (n+1)-th circuit layer on a side of the n-th dielectric layer away from the base substrate, the (n+1)-th circuit layer being electrically connected with the n-th circuit layer through the n-th via, N being a positive integer greater than 1, 1≤n≤N, and n being an integer.

### CROSS-REFERENCE TO RELATED APPLICATION

This application is based upon and claims priority to Chinese Patent Application No. 201911330953.3, filed Dec. 20, 2019, the entire contents of which are incorporated herein by reference.

### TECHNICAL FIELD

The present disclosure relates to the field of circuit board technology and, more particularly, to an electronic apparatus, a circuit board, and a method of manufacturing the same.

### BACKGROUND

A printed circuit board (PCB) is usually formed using a copper clad laminate through pressing, and is used as a carrier and connector of various electronic devices. A high density interconnector (HDI) type PCB has been rapidly developed with the impetus of factors, such as the requirements for a short, small, light and thin PCB, an increased degree of integration of a chip, increased number of pins, and introduction of an advanced package. An HDI board has laser-drilled holes instead of through holes in a traditional PCB and meanwhile, an exposure machine having a higher accuracy is equipped, thereby achieving a significant increase in a wiring density of the HDI board.

However, an advanced PCB, such as any stage of an HDI board, has a low yield, which is mainly limited by existing processes in which each additional stage of laser-drilled hole requires one-time pressing, and expansion and shrinkage due to pressing may cause the yield of final products to be decreased.

The above information disclosed in this Background section is only for enhancement of understanding of the background of the present disclosure, and therefore, it may contain information that does not constitute the prior art that is already known to those ordinary skilled in the art.

### SUMMARY

An objection of the present disclosure is to provide an electronic apparatus, a board, and a method of manufacturing the same, thereby increasing a yield of the circuit board.

In order to achieve the above objection of the invention, the present disclosure adopts the technical solution as follows.

According to a first aspect of the present disclosure, there is provided a method of manufacturing a circuit board, which comprises:

providing a base substrate;

forming a first circuit layer on a side of the base substrate; and

performing a first circuit stacking operation to an N-th circuit stacking operation in sequence, wherein an n-th circuit stacking operation comprises:

forming an n-th dielectric layer on a side of an n-th circuit layer away from the base substrate, the n-th dielectric layer being provided with at least one n-th via exposing the n-th circuit layer; and

forming an (n+1)-th circuit layer on a side of the n-th dielectric layer away from the base substrate, the (n+1)-th circuit layer being electrically connected with the n-th circuit layer through the n-th via,

wherein N is a positive integer greater than 1; and 1≤n≤N and n is an integer.

In one exemplary embodiment of the present disclosure, the forming of the (n+1)-th circuit layer comprises:

forming an (n+1)-th metal thin film layer on the side of the n-th dielectric layer away from the base substrate;

thickening the (n+1)-th metal thin film layer to an expected thickness through an electroplating process to obtain an (n+1) metal layer; and

performing patterning operation on the (n+1)-th circuit layer to obtain the (n+1)-th circuit layer.

In one exemplary embodiment of the present disclosure, the expected thickness is in a range of 10 μm-20 μm.

In one exemplary embodiment of the present disclosure, the forming of the n-th dielectric layer comprises:

coating a resin on the side of the n-th circuit layer away from the base substrate to form an n-th resin material layer; and

patterning the n-th resin material layer to form the n-th via exposing the n-th circuit layer.

In one exemplary embodiment of the present disclosure, the resin is a resin for a photoresist; and

the patterning of the n-th resin material layer comprises:

exposing an n-th preset region of the n-th resin material layer; and

developing to remove a portion or all of the resin in the n-th preset region.

In one exemplary embodiment of the present disclosure, the method of manufacturing the circuit board further comprises:

forming a base buffer layer on the side of the base substrate;

the forming of the first circuit layer on the side of the base substrate comprises:

forming the first circuit layer on a surface of the base substrate away from the base substrate.

In one exemplary embodiment of the present disclosure, the forming of the n-th dielectric layer further comprises:

before forming the n-th resin material layer, forming an n-th first buffer material layer on the side of the n-th circuit layer away from the base substrate;

the coating of the resin on the side of the n-th circuit layer away from the base substrate comprises:

coating the resin on a surface of the n-th first buffer material layer away from the base substrate to form the n-th resin material layer; and

after patterning the n-th resin material layer, the method of manufacturing the circuit board further comprises:

patterning the n-th first buffer material layer to obtain the n-th via exposing the n-th circuit layer.

In one exemplary embodiment of the present disclosure, the forming of the n-th dielectric layer further comprises:

after forming the n-th resin material layer, forming an n-th second buffer material layer on a surface of the n-th resin material layer away from the base substrate; and

before patterning the n-th resin material layer, the method of manufacturing the circuit board further comprises:

patterning the n-th second buffer material layer to expose a portion to be patterned of the n-th resin material layer.

In one exemplary embodiment of the present disclosure, the method of manufacturing the circuit board further comprises: before forming the first circuit layer,

forming at least one connection hole on the base substrate;

filling the connection hole with a conductive material; and

forming a backside circuit on a side of the base substrate such that the backside circuit and the first circuit layer are position on both sides of the base substrate which are opposite to each other, the backside circuit being electrically connected with the conductive material in the connection hole; and

the forming of the first circuit layer on the side of the base substrate comprises:

forming the first circuit layer on the side of the base substrate such that the first circuit layer is electrically connected with the conductive material in the connection hole.

According to a second aspect of the present disclosure, there is provided a circuit board comprising a base substrate, a first circuit layer, and first to N-th stacking layers, which are sequentially laminated, wherein an n-th stacking layer comprises:

an n-th dielectric layer disposed on a side of an n-th circuit layer away from the base substrate, the n-th dielectric layer being provided with at least one n-th via exposing an n-th circuit layer, wherein a material of the n-th dielectric layer comprises a resin for a photoresist; and

an (n+1)-th circuit layer disposed on a side of the n-th dielectric layer away from the base substrate, the (n+1)-th circuit layer being electrically connected with the n-th circuit layer through the n-th via;

wherein N is a positive integer greater than 1; and 1≤n≤N and n is an integer.

In one exemplary embodiment of the present disclosure, the n-th dielectric layer comprises an n-th resin layer, and further comprises an n-th first buffer layer and/or an n-th second buffer layer, wherein,

the n-th resin layer is disposed on a side of the n-th circuit layer away from the base substrate;

the n-th first buffer layer is disposed on the side of the n-th circuit layer away from the base substrate and on a surface of the n-th resin layer away from the base substrate; and

the n-th second buffer layer is disposed on the surface of the n-th resin layer away from the base substrate.

In one exemplary embodiment of the present disclosure, the base substrate is provided with at least one connection hole being filled with a conductive material; and

the circuit board further comprises:

a backside circuit disposed on a side of the base substrate away from the first circuit layer, the backside circuit being electrically connected with the first circuit layer through the conductive material in the connection hole.

According to a third aspect of the present disclosure, there is provided an electronic apparatus comprising the circuit board described as above.

### BRIEF DESCRIPTION OF THE DRAWINGS

The above and other features and advantages of the present disclosure will become more apparent by describing in detail example implementations thereof with reference to the attached drawings.

FIG. 1 is a schematic structural view of forming a first metal thin film layer of an embodiment of the present disclosure.

FIG. 2 is a schematic structural view of forming a first metal layer of an embodiment of the present disclosure.

FIG. 3 is a schematic structural view of forming a first circuit layer of an embodiment of the present disclosure.

FIG. 4 is a schematic structural view of forming a first resin material layer of an embodiment of the present disclosure.

FIG. 5 is a schematic structural view of forming a first resin layer of an embodiment of the present disclosure.

FIG. 6 is a schematic structural view of an N-stage circuit board of an embodiment of the present disclosure.

FIG. 7 is a schematic structural view of a 7-stage circuit board of an embodiment of the present disclosure.

FIG. 8 is a schematic structural view of a 7-stage circuit board of an embodiment of the present disclosure.

FIG. 9 is a schematic structural view of a 7-stage circuit board having double-sided wirings of an embodiment of the present disclosure.

FIG. 10 is a schematic flowchart of a manufacturing method of a circuit board of an embodiment of the present disclosure.

### DETAILED DESCRIPTION

Example embodiments will now be described more fully with reference to the accompanying drawings. However, the example embodiments can be implemented in various forms and should not be construed as limited to the embodiments set forth herein. Rather, these embodiments are provided so that the present disclosure will be more thorough and complete, and will fully convey the concept of the example embodiments to those skilled in the art. The described features, structures, or characteristics can be combined in one or more embodiments in any suitable manner. In the following description, many specific details are provided to give a full understanding of the embodiments of the present disclosure.

In the drawings, thicknesses of regions and layers may be exaggerated for clarity. The same reference numerals in the drawings refer to the same or similar structures and thus, detailed description thereof will be omitted.

The described features, structures, or characteristics may be combined in one or more embodiments in any suitable manner. In the following description, many specific details are provided to give a full understanding of the embodiments of the present disclosure. However, those skilled in the art will realize that the technical solutions of the present disclosure may be practiced without one or more of the specific details, or other methods, components, materials, and the like, may be utilized. In other cases, well-known structures, materials, or operations are not illustrated or described in detail to avoid obscuring the main technical ideas of the present disclosure.

When a structure is “on” other structure, it may mean that the structure is integrally formed on the other structure, or that the structure is “directly” arranged on the other structure, or that the structure is “indirectly” arranged on the other structure through another structure.

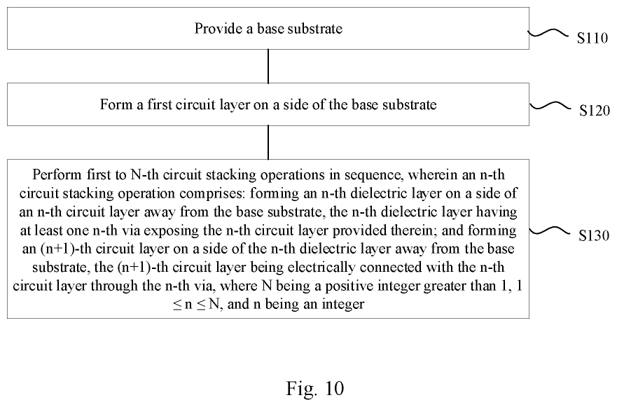

In an embodiment of the present disclosure, there is provided a method of manufacturing a circuit board, as shown in FIG. 10, including:

step S110, as shown in FIG. 3, providing a base substrate 100;

step S120, as shown in FIG. 3, forming a first circuit layer 201 on a side of the base substrate 100; and

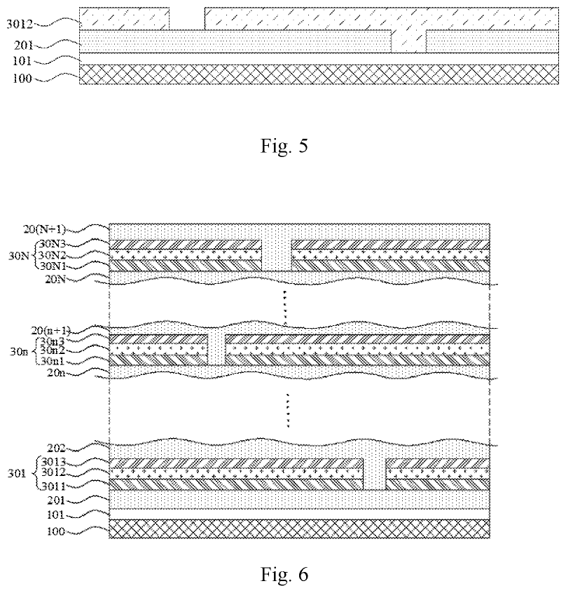

step S130, as shown in FIGS. 4 to 6, performing a first circuit stacking operation to an N-th circuit stacking operation in sequence, wherein an n-th circuit stacking operation includes:
step S210n, forming an n-th dielectric layer 30n on a side of an n-th circuit layer 20n away from the base substrate 100, the n-th dielectric layer 30n having at least one n-th via exposing the n-th circuit layer 20n provided therein; and
step S220n, forming an (n+1)-th circuit layer 20(n+1) on a side of the n-th dielectric layer 30n away from the base substrate 100, the (n+1)-th circuit layer 20(n+1) being electrically connected with the n-th circuit layer 20n through the n-th via;

wherein N is a positive integer greater than 1; and 1≤n≤N, and n is an integer.

According to the method of manufacturing a circuit board provided by the present disclosure, during manufacturing, respective circuit layers and respective dielectric layers may be sequentially laminated on the base substrate 100, and thus an N-stage circuit board may be formed. Since the respective circuit layers and the respective dielectric layers are disposed on a same side of the base substrate 100, it is unnecessary for the circuit board to have the respective circuit layers and the respective dielectric layers formed on both sides of the base substrate 100 by pressing, thereby avoiding structural changes due to expansion and contraction of materials and structures of respective layers during pressing, especially avoiding defects such as internal short circuit, hole deviation, layer deviation, and the like, caused by pressing.

Further, the method of manufacturing a circuit board provided by the present disclosure is suitable for adopting a semiconductor process such as a thin film transistor-liquid crystal display (TFT-LCD) process. In the TFT-LCD process, films/layers are sequentially formed on the base substrate 100, and vias can be formed through dielectric layers through a patterning process to connect two adjacent circuit layers, so that any stage of a circuit structure may be accordingly formed with a cost having no considerable increase as compared to an HDI board. In addition to that, the TFT-LCD process may achieve more accurate alignment with a small deviation, for example, generally no more than 1.5 micrometers (μm), reduce sizes of vias of a circuit board, and reduce line widths and pitches of circuit leading wirings, thereby further improving an interconnect density of the circuit board.

Respective steps of the method of manufacturing a circuit board provided by the embodiment of the present disclosure will be described in detail below with reference to the drawings.

In step S110, the base substrate 100 may be provided as a base substrate 100 of an inorganic material, and may also be a base substrate 100 of an organic material. As an example, in one embodiment of the present disclosure, the base substrate 100 may include a glass material such as soda-lime glass, quartz glass, sapphire glass, or the like. In another embodiment of the present disclosure, the base substrate 100 may include polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN), or a combination thereof. In another embodiment of the present disclosure, the base substrate 100 may also be a flexible base substrate 100, and for example, a material of the base substrate 100 may be polyimide (PI).

It can be understood that when the base substrate 100 is provided as a flexible base substrate 100, the circuit board thus manufactured may be a flexible circuit board.

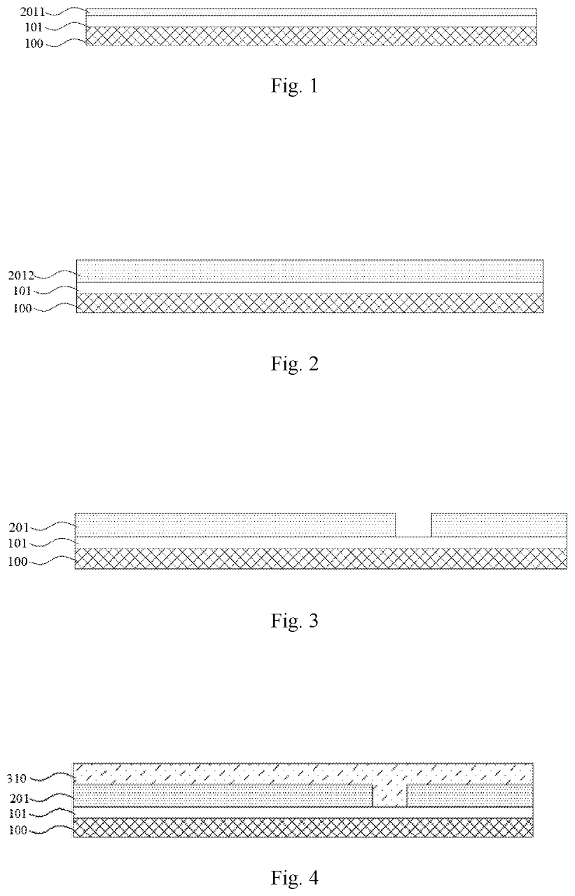

In step S120, the first circuit layer 201 may be formed on the side of the base substrate 100 via a photolithography process. As an example, as shown in FIG. 2, a first metal layer 2012 may be formed on one side of the base substrate 100, and then be patterned.

A thickness of the first metal layer 2012 may be determined according to design requirements for the circuit board, and it may be several hundred nanometers (nm), several micrometers (μm), or 10-20 μm. If the circuit board thus manufactured has stricter requirements on an impedance of a circuit, has a larger size, and requires greater operating current and operating voltage, etc., the thickness of the first metal layer 2012 may be greater, so that the first circuit layer 201 has a wiring with a greater thickness and a smaller square resistance.

For the first metal layer 2012 with a relatively thinner thickness, for example, with a thickness of several hundred nanometers (nm), or with a thickness of about 1 μm, it may be formed by a sputtering process. That is, on the premise of satisfying the requirements of the first circuit layer 201, a relatively thin first metal thin film layer may be formed as the first metal layer 2012 by sputtering.

For the first metal layer with a relatively thicker thickness, as shown in FIG. 1, a first metal thin film layer 2011 can be formed thinly, for example, with a thickness of no greater than 1 μm, by sputtering, and then be electroplated as a seed layer, so that the first metal thin film layer 2011 is increased to an expected thickness of, for example, 10 to 20 μm, and thus a required first metal layer 2012 is obtained.

The first metal layer 2012 may be patterned by the following method:

step S310, forming a first photoresist layer on a side of the first metal layer 2012 away from the base substrate 100;

step S320, exposing and developing the first photoresist layer to expose a portion of the first metal layer 2012 that needs to be removed;

step S330, etching the exposed portion of the first metal layer 2012, and then patterning the first metal layer 2012 to obtain the required first circuit layer 201; and

step S340, removing the remaining first photoresist layer.

A material of the first metal layer 2012 may be platinum, gold, silver, aluminum, chromium, nickel, copper, molybdenum, titanium, magnesium, calcium, barium, sodium, palladium, iron, manganese, or a combination thereof. As an example, in one embodiment of the present disclosure, the material of the first metal layer 2012 may be copper.

Optionally, as shown in FIG. 1, the method of manufacturing a circuit board may further include forming a base buffer layer 101 on the side of the base substrate 100. In step S120, a first circuit layer 201 is formed on a surface of the base buffer layer 101 away from the base substrate 100. As such, the base buffer layer 101 is formed between the first circuit layer 201 and the base substrate 100, and may both provide a planarized surface for the first metal layer 2012 and the first circuit layer 201, and enhance an adhesion force between the first metal layer 2012 and the first circuit layer 201, thereby improving a reliability and reliability of the manufactured circuit board.

Optionally, a material of the base buffer layer 101 may be an inorganic material, and for example, may be an inorganic insulating material such as silicon nitride, silicon oxide, silicon oxynitride, or the like. Optionally, the base buffer layer 101 may have a thickness of 1-10 μm.

In one embodiment of the present disclosure, the base buffer layer 101 may be formed by a deposition method, and for example, a silicon nitride layer may be formed as the base buffer layer 101 by a plasma enhanced chemical vapor deposition (PECVD) method.

In step S130, as shown in FIGS. 4-7, first to N-th circuit stacking operations may be performed in sequence so that a first dielectric layer 301, a second circuit layer 202, a second dielectric layer, a third circuit layer 203, a third dielectric layer 303, . . . , an n-th dielectric layer 30n, an (n+1)-th circuit layer 20(n+1) are sequentially formed on the side of the first circuit layer 201 away from the base substrate 100, until an (N+1)-th circuit layer is formed. As such, the circuit board having N+1 circuit layers may be formed.

Wherein any of the circuit stacking operations includes an operation of forming a dielectric layer and an operation of forming a circuit layer that are performed in sequence. In other words, the n-th circuit stacking operation includes:

step S210n, forming an n-th dielectric layer 30n on a side of an n-th circuit layer 20n away from the base substrate 100, the n-th dielectric layer 30n having at least one n-th via that exposes the n-th circuit layer 20n provided therein; and

step S220n, forming an (n+1)-th circuit layer 20(n+1) on a side of the n-th dielectric layer 30n away from the base substrate 100, the (n+1)-th circuit layer 20(n+1) being electrically connected with the n-th circuit layer 20n through the n-th via.

As an example, the first circuit stacking operation includes:

step S2101, forming a first dielectric layer 301 on a side of a first circuit layer 201 away from the base substrate 100, the first dielectric layer 301 having at least one first via that exposes the first circuit layer 201 provided therein; and

step S2201, forming a second circuit layer 202 on a side of the first dielectric layer 301 away from the base substrate 100, the second circuit layer 202 being electrically connected with the first circuit layer 201 through the first via.

As another example, the seventh circuit stacking operation includes:

step S2107, forming a seventh dielectric layer 307 on a side of a seventh circuit layer 207 away from the base substrate 100, the seventh dielectric layer 307 having at least one seventh via that exposes the seventh circuit layer 207 provided therein; and

step S2207, forming an eighth circuit layer 208 on a side of the seventh dielectric layer 307 away from the base substrate 100, the eighth circuit layer 208 being electrically connected with the seventh circuit layer 207 through the seventh via.

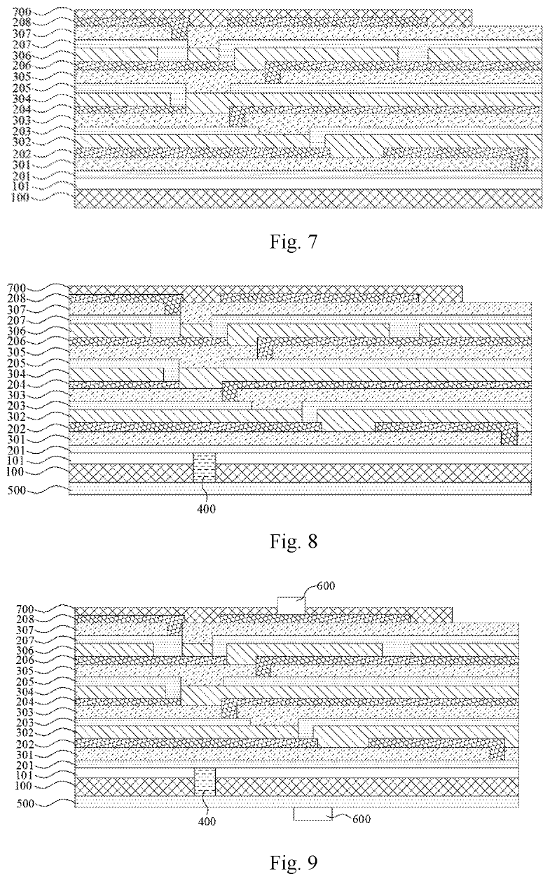

As such, by means of the method of manufacturing a circuit board provided by the present disclosure, the circuit layers and the dielectric layers may be sequentially stacked on the base substrate to finally form the required circuit board. As an example, as shown in FIG. 7, when N is 7, the formed circuit board may include the base substrate 100, the base buffer layer 101, the first circuit layer 201, the first dielectric layer 301, the second circuit layer 202, a second dielectric layer 302, a third circuit layer 203, a third dielectric layer 303, a fourth circuit layer 204, a fourth dielectric layer 304, a fifth circuit layer 205, a fifth dielectric layer 305, a sixth circuit layer 206, a sixth dielectric layer 306, the seventh circuit layer 207, the seventh dielectric layer 307, and the eighth circuit layer 208, which are sequentially laminated.

In step S210n, a required n-th dielectric layer 30n may be formed by the following method:

step S410n, forming an n-th resin material layer by coating a resin on a side of the n-th circuit layer 20n away from the base substrate 100; and

step S420n, patterning the n-th resin material layer to obtain an n-th via that exposes the n-th circuit layer 20n, the remaining n-th resin material layer being used as the n-th resin layer 30n2 of the circuit board.

As such, in the method for manufacturing a circuit board provided by the present disclosure, the dielectric layers may be formed without pressing, which avoids deformation and displacement of circuit leading wirings during pressing, is beneficial to improve alignment accuracy during manufacturing a circuit board, and improves an interconnection density and yield of the circuit board.

Optionally, in step S410n, the coated resin may be a resin for a photoresist, and for example, can be a polyimide resin (PI). As such, the n-th resin material layer may be patterned by means of a photolithography process. As an example, the n-th resin layer 30n2 may be obtained by exposing an n-th preset region of the n-th resin material layer at first, and then developing to remove a portion or all of the resin in the n-th preset region. It can be understood that the n-th resin layer 30n2 is formed with an n-th via in the n-th preset region to expose the n-th circuit layer 20n.

As an example, as shown in FIG. 4, a first resin layer 3012 can be obtained by forming a first resin material layer 310 on a side of the first circuit layer 201 away from the base substrate 100, and then patterning the first resin material layer 310.

In this embodiment, since the n-th resin material layer can be patterned by means of a photolithography process without using a laser drilling process, higher alignment accuracy and a smaller size of via can be achieved, thereby achieving interconnection with a higher density. In particular, the method of manufacturing a circuit board may achieve a higher-precision alignment by means of the TFT-LCD process.

Optionally, in order to improve an adhesion force between the n-th resin material layer and the n-th circuit layer 20n, an n-th first buffer material layer may be further formed on the side of the n-th circuit layer 20n away from the base substrate 100 prior to step S410n in step S210n, an n-th resin material layer may be formed by coating resin on a surface of the n-th first buffer material layer away from the base substrate 100 in step S410n, and after step S420n, an n-th first buffer layer 30n1 may be formed by patterning the n-th buffer material layer to obtain an n-th via that exposes the n-th circuit layer 20n.

In other words, in step S210n, the n-th dielectric layer 30n may be formed by forming the laminated n-th first buffer material and resin material layers on the side of the n-th circuit layer 20n away from the base substrate 100 in sequence, and patterning the n-th resin material layer and the n-th first buffer material layer in sequence, as shown in FIG. 6, to obtain the n-th first buffer layer 30n1 and the n-th resin layer 30n2 sequentially stacked on the side of the n-th circuit layer 20n away from the base substrate 100.

As such, as shown in FIG. 6, the formed n-th dielectric layer 30n includes the n-th first buffer layer 30n1 and the n-th resin layer 30n2 that are sequentially laminated on the side of the n-th circuit layer 20n away from the base substrate 100, and the n-th via penetrates the n-th first buffer layer 30n1 and the n-th resin layer 30n2 to expose the n-th circuit layer 20n.

A material of the n-th first buffer material layer may be an inorganic material, and for example, may be an inorganic insulating material such as silicon nitride, silicon oxide, silicon oxynitride, or the like. Optionally, the n-th first buffer material layer may have a thickness of 1-10 μm. In one embodiment of the present disclosure, the n-th first buffer material layer may have the same material as that of the base buffer layer 101.

In one embodiment of the present disclosure, the n-th first buffer material layer may be formed by a deposition method, and for example, a silicon nitride layer may be formed as the n-th first buffer material layer by a PECVD method.

Optionally, in order to improve an adhesion force between the n-th resin material layer and the (n+1)-th circuit layer 20(n+1), in step S210n, an n-th second buffer material layer is formed on a surface of the n-th resin material layer away from the base substrate 100 after step S410n, and the n-th second buffer material layer is also patterned before step S410n to expose a portion of the n-th resin material layer to be patterned, so that an n-th second buffer layer 30n3 is formed as shown in FIG. 6.

In other words, in step S210n, the n-th dielectric layer 30n may be formed by forming an n-th resin material layer and an n-th second buffer material layer, which are laminated, on the side of the n-th circuit layer 20n away from the base substrate 100 in sequence, and patterning the n-th second buffer material layer and the n-th resin material layer in sequence to obtain the n-th resin layer 30n2 and the n-th second buffer layer 30n3 sequentially laminated on the side of the n-th circuit layer 20n away from the base substrate 100.

As such, as shown in FIG. 6, the formed n-th dielectric layer 30n includes the n-th resin layer 30n2 and the n-th second buffer layer 30n3 that are sequentially laminated on the side of the n-th circuit 20n away from the base substrate 100, and the n-th via penetrates the n-th resin layer 30n2 and the n-th second buffer layer 30n3 to expose the n-th circuit layer 20n.

A material of the n-th second buffer material layer may be an inorganic material, for example, an inorganic insulating material such as silicon nitride, silicon oxide, silicon oxynitride, or the like. Optionally, the n-th second buffer material layer may have a thickness of 1-10 μm. In one embodiment of the present disclosure, the n-th second buffer material layer has the same material as that of the base buffer layer 101.

In one embodiment of the present disclosure, the n-th second buffer material layer may be formed by a deposition method, and for example, a silicon nitride layer may be formed as the n-th second buffer material layer by a PECVD method.

Of course, as shown in FIG. 6, in the method of manufacturing a circuit board of the present disclosure, an n-th dielectric layer 30n consisting of an n-th first buffer layer 30n1, an n-th resin layer 30n2, and an n-th second buffer layer 30n3 that are sequentially laminated may also be provided. As an example, the n-th dielectric layer 30n may be formed by firstly forming an n-th first buffer material layer, an n-th resin material layer, and an n-th second buffer material layer on the side of the n-th circuit layer 20n away from the base substrate 100 in sequence, and then patterning the n-th second buffer material layer, the n-th resin material layer, and the n-th first buffer material layer in sequence.

In step S220n, an (n+1)-th circuit layer 20(n+1) may be formed on a side of the nth dielectric layer 30n away from the base substrate 100, and the (n+1)-th circuit layer 20(n+1) is electrically connected to the n-th circuit layer 20n through the n-th via. The (n+1)-th circuit layer 20(n+1) may be formed using the same method as that of the first circuit layer 201. As an example, the (n+1)-th circuit layer 20(n+1) can be obtained in such a way that an (n+1) metal layer is formed by forming an (n+1)-th metal thin film layer on the side of the n-th dielectric layer 30n away from the base substrate 100 at first, and then thickening the (n+1)-th metal thin film layer to an expected thickness through an electroplating process, and next a patterning operation is performed on the (n+1)-th metal layer. Further, the expected thickness is in a range of 10-20 μm.

Further, the electroplating process may be performed using an anisotropic electroplating solution, such that the portion of the (n+1)-th metal thin film layer in the n-th via has a thickness with a relatively greater thickening rate, and the portion of the (n+1)-th metal thin film layer on the n-th dielectric layer 30n has a thickness with a relatively smaller thickening rate, and thus the n-th layer via is capable of being filled or substantially filled with the n-th metal layer.

In order to manufacture a circuit board for double-sided wiring, as shown in FIGS. 8 and 9, the method for manufacturing a circuit board of the present disclosure may further include:

Step S510, forming at least one connection hole on the base substrate 100 before step S120;

Step S520, filling the connection hole with a conductive material 400; and

Step S530, forming a backside circuit 500 on one side of the base substrate 100, such that the backside circuit 500 and the first circuit layer 201 are positioned on both sides of the base substrate 100 opposite to each other, wherein the backside circuit 500 is electrically connected the conductive material 400 in the connection hole.

In Step 120, the first circuit layer 201 is formed on one side of the base substrate 100, and the first circuit layer 201 is electrically connected to the conductive material 400 in the connection hole.

As such, the formed circuit board includes the backside circuit 500 being electrically connected with the first circuit layer 201. If required, the electronic component 600 can be connected to the (N+1)-th circuit layer 20(N+1) and the backside circuit 500 to realize double-sided wirings.

In step S510, the connection hole as desired may be formed on the base substrate 100 using mechanical drilling, etch drilling, laser drilling, or other manners. As an example, the connection hole as required may be formed on a glass substrate using a glass drilling method.

In step S520, the connection hole may be filled with a metal such as copper so as to be used as the conductive material 400, thereby achieving electrical connection between the first circuit layer 201 and the backside circuit 500.

In step 530, the backside circuit 500 may be formed in the same or similar method as the first circuit layer 201. As an example, the backside circuit 500 may be formed by forming a backside metal material layer on the side of the base substrate 100 where the backside circuit 500 is to be formed, and then patterning the backside metal material layer. The backside circuit 500 may have a material and a thickness identical to or different from those of the first circuit layer 201, but the present disclosure makes no special limitation on this.

It can be understood that step 530 may be performed first, and then step S120 may be performed, or step S120 may be performed first, and then step 530 may be performed, or respective processes in step 530 and respective processes in step 120 may also be executed simultaneously or alternately, but the present disclose makes no special limitation on this.

The method of manufacturing the circuit board of present disclosure, as shown in FIG. 7, may further include forming a protective layer 700 on a side of the (N+1)-th circuit layer 20(N+1) away from the base substrate 100, and for example, coating a liquid photoresist coated on the side of the (N+1)-th circuit layer 20(N+1) away from the base substrate 100. Furthermore, an electronic component 600 required may be connected to the (N+1)-th circuit layer 20(N+1).

When the circuit board manufactured according to the present disclosure further includes a backside circuit 500, the method of manufacturing the circuit board of the present disclosure may further include forming a protective layer 700 on a side of the backside circuit 500 away from the base substrate 100, and for example, coating a liquid photoresist on the side of the backside circuit 500 away from the base substrate 100. Further, an electronic components 600 required may also be connected to the backside circuit 500, thereby achieving double-sided wiring on the circuit board.

An embodiment of the present disclosure also provides a circuit board, as shown in FIG. 6, including a base substrate 100, a first circuit layer 201, a first stack layer to an N-th stack layer, which are sequentially laminated, wherein the n-th stack layer includes an n-th dielectric layer 30n and an (n+1)-th layer circuit 20(n+1);

the n-th dielectric layer 30n is provided on a side of the n-th circuit layer 20n away from the base substrate 100, and has at least one n-th via exposing the n-th circuit layer 20n provided therein, wherein the n-th dielectric layer 30n includes a material such as a resin for a photoresist;

the (n+1)-th circuit layer 20(n+1) is provided on a side of the n-th dielectric layer 30n away from the base substrate 100, and is electrically connected with the n-th circuit layer 20 through the n-th via; and

wherein N is a positive integer greater than 1, and 1≤n≤N, and n is an integer.

The circuit board according to the present disclosure may be manufactured using the method of manufacturing a circuit board described as above, and its specific details, principles and effects are described and introduced in detail in the above-mentioned method of manufacturing a circuit board in the above implementations, and thus are not repeated any more. In particular, the circuit board provided by the present disclosure can avoid the use of a processing process, and especially can be manufactured using the TFT-LCD process and thus, can have a high production yield, more easily achieve a higher alignment accuracy, a greater wiring density, and a greater interconnection density, and more easily reduce an area of the circuit board and improve an electrical performance of the circuit board.

Preferably, as shown in FIG. 6, the n-th dielectric layer 30n includes the n-th resin layer 30n2, and further includes the n-th first buffer layer 30n1 and/or the n-th second buffer layer 30n3, wherein:

the n-th resin layer 30n2 is disposed on the side of the n-th circuit layer 20n away from the base substrate 100;

the n-th first buffer layer 30n1 is disposed on the side of the n-th circuit layer 20n away from the base substrate 100, and the n-th resin layer 30n2 is close to a surface of the base substrate; and

the n-th second buffer 30n3 is disposed on the side of the n-th resin layer 30n2 away from the base substrate.

Preferably, as shown in FIG. 9, the base substrate 100 is provided with the at least one connection hole which is filled with the conductive material 400, the circuit board further includes the backside circuit 500 provided on the side of the base substrate 100 away from the first circuit layer 201, and the backside circuit 500 and the first circuit layer 201 are electrically connected through the conductive material 400 in the connection hole. As such, the circuit board may be used to double-sided wring.

An embodiment of the present disclosure also provides an electronic apparatus which includes any of the circuit boards described in the foregoing embodiments. The electronic apparatus may be a smart phone, a notebook computer, a wearable device, or other types of electronic apparatuses. Since the electronic apparatus has any one of the circuit boards described in the foregoing embodiments, it has the same beneficial effects, and thus is not repeated herein in the present disclosure.

It should be noted that although the respective steps of the method in the present disclosure are described in a specific order in the drawings, this does not require or imply that the steps must be performed in the specific order, or all steps shown must be performed to achieve desired results. Additionally or alternatively, certain steps may be omitted, multiple steps may be combined into one step for execution, and/or one step may be split into multiple steps for execution, and the like.

It should be understood that the present disclosure will be not limit application thereof to detailed structures and arrangement of parts disclosed in this specification. The present disclosure can have other implementations and can be achieved and performed in many manners. The aforementioned modified and varied forms fall within the scope of the present disclosure. It should be understood that the present disclosure disclosed and defined in this specification extends to all alternative combinations of two or more individual features mentioned or evident in the context and/or drawings. All of these different combinations constitute various alternative aspects of the present disclosure. The embodiments of the present specification describe the best modes known for implementing the present disclosure, and will enable those skilled in the art to utilize the present disclosure.

1. A method of manufacturing a circuit board, comprising:
providing a base substrate;
forming a first circuit layer on a side of the base substrate; and
performing a first circuit stacking operation to an N-th circuit stacking operation in sequence, wherein an n-th circuit stacking operation comprises:
forming an n-th dielectric layer on a side of an n-th circuit layer away from the base substrate, the n-th dielectric layer having at least one n-th via exposing the n-th circuit layer provided therein; and
forming an (n+1)-th circuit layer on a side of the n-th dielectric layer away from the base substrate, the (n+1)-th circuit layer being electrically connected with the n-th circuit layer through the n-th via,
wherein N is a positive integer greater than 1; and 1≤n≤N, and n is an integer.

2. The method of manufacturing the circuit board according to claim 1, wherein the forming of the (n+1)-th circuit layer comprises:
forming an (n+1)-th metal thin film layer on the side of the n-th dielectric layer away from the base substrate;
thickening the (n+1)-th metal thin film layer to an expected thickness through an electroplating process to obtain an (n+1) metal layer; and
performing patterning operation on the (n+1)-th circuit layer to obtain the (n+1)-th circuit layer.

3. The method of manufacturing the circuit board according to claim 2, wherein the expected thickness is in a range of 10 μm-20 μm.

4. The method of manufacturing the circuit board according to claim 1, wherein the forming of the n-th dielectric layer comprises:
coating a resin on the side of the n-th circuit layer away from the base substrate to form an n-th resin material layer; and
patterning the n-th resin material layer to form the n-th via exposing the n-th circuit layer.

5. The method of manufacturing the circuit board according to claim 4, wherein the resin is a resin for a photoresist; and
wherein the patterning of the n-th resin material layer comprises:
exposing an n-th preset region of the n-th resin material layer; and
developing to remove a portion or all of the resin in the n-th preset region.

6. The method of manufacturing the circuit board according to claim 1, further comprising:
forming a base buffer layer on the side of the base substrate,
wherein the forming of the first circuit layer on the side of the base substrate comprises: forming the first circuit layer on a surface of the base substrate away from the base substrate.

7. The method of manufacturing the circuit board according to claim 4, wherein the forming of the n-th dielectric layer further comprises:
before forming the n-th resin material layer, forming an n-th first buffer material layer on the side of the n-th circuit layer away from the base substrate,
wherein the coating of the resin on the side of the n-th circuit layer away from the base substrate comprises: coating the resin on a surface of the n-th first buffer material layer away from the base substrate to form the n-th resin material layer, and
after patterning the n-th resin material layer, the method of manufacturing the circuit board further comprises: patterning the n-th first buffer material layer to obtain the n-th via exposing the n-th circuit layer.

8. The method of manufacturing the circuit board according to claim 4, wherein the forming of the n-th dielectric layer further comprises:
after forming the n-th resin material layer, forming an n-th second buffer material layer on a surface of the n-th resin material layer away from the base substrate, and
before patterning the n-th resin material layer, the method further comprises: patterning the n-th second buffer material layer to expose a portion to be patterned of the n-th resin material layer.

9. The method of manufacturing the circuit board according to claim 1, further comprising, before forming the first circuit layer:
forming at least one connection hole on the base substrate;
filling the connection hole with a conductive material; and
forming a backside circuit on a side of the base substrate such that the backside circuit and the first circuit layer are position on both sides of the base substrate which are opposite to each other, the backside circuit being electrically connected with the conductive material in the connection hole, and
wherein the forming of the first circuit layer on the side of the base substrate comprises: forming the first circuit layer on the side of the base substrate such that the first circuit layer is electrically connected with the conductive material in the connection hole.

10. A circuit board, comprising:
a base substrate, a first circuit layer, and first to N-th stacking layers, which are sequentially laminated, wherein an n-th stacking layer comprises:
an n-th dielectric layer disposed on a side of an n-th circuit layer away from the base substrate, the n-th dielectric layer being provided with at least one n-th via exposing the n-th circuit layer, wherein a material of the n-th dielectric layer comprises a resin for a photoresist; and
an (n+1)-th circuit layer disposed on a side of the n-th dielectric layer away from the base substrate, the (n+1)-th circuit layer being electrically connected with the n-th circuit layer through the n-th via,
wherein N is a positive integer greater than 1; and 1≤n≤N and n is an integer.

11. The circuit board according to claim 10, wherein the n-th dielectric layer comprises an n-th resin layer, and further comprises at least one of: an n-th first buffer layer and an n-th second buffer layer; and wherein:
the n-th resin layer is disposed on a side of the n-th circuit layer away from the base substrate;
the n-th first buffer layer is disposed on the side of the n-th circuit layer away from the base substrate and on a surface of the n-th resin layer away from the base substrate; and
the n-th second buffer layer is disposed on the surface of the n-th resin layer away from the base substrate.

12. The circuit board according to claim 10, wherein the base substrate is provided with at least one connection hole being filled with a conductive material, and
wherein the circuit board further comprises: a backside circuit disposed on a side of the base substrate away from the first circuit layer, the backside circuit being electrically connected with the first circuit layer through the conductive material in the connection hole.

13. An electronic apparatus comprising a circuit board, the circuit board comprising a base substrate, a first circuit layer, and first to N-th stacking layers, which are sequentially laminated, wherein an n-th stacking layer comprises:
an n-th dielectric layer disposed on a side of an n-th circuit layer away from the base substrate, the n-th dielectric layer being provided with at least one n-th via exposing the n-th circuit layer, wherein a material of the n-th dielectric layer comprises a resin for a photoresist; and
an (n+1)-th circuit layer disposed on a side of the n-th dielectric layer away from the base substrate, the (n+1)-th circuit layer being electrically connected with the n-th circuit layer through the n-th via,
wherein N is a positive integer greater than 1; and 1≤n≤N and n is an integer.

14. The electronic apparatus according to claim 13, wherein the n-th dielectric layer comprises an n-th resin layer, and further comprises at least one of: an n-th first buffer layer and an n-th second buffer layer; and wherein:
the n-th resin layer is disposed on a side of the n-th circuit layer away from the base substrate;
the n-th first buffer layer is disposed on the side of the n-th circuit layer away from the base substrate and on a surface of the n-th resin layer away from the base substrate; and
the n-th second buffer layer is disposed on the surface of the n-th resin layer away from the base substrate.

15. The electronic apparatus according to claim 13, wherein the base substrate is provided with at least one connection hole being filled with a conductive material, and
wherein the circuit board further comprises: a backside circuit disposed on a side of the base substrate away from the first circuit layer, the backside circuit being electrically connected with the first circuit layer through the conductive material in the connection hole.
